(19) United States
(12) Patent Application Publication
(10) Pub. No.: US 2014/0225248 A1
(43) Pub. Date: Aug. 14, 2014

(54) POWER DISTRIBUTION AND THERMAL SOLUTION FOR DIRECT STACKED INTEGRATED CIRCUITS

(71) Applicant: QUALCOMM INCORPORATED, San Diego, CA (US)

(72) Inventors: Brian M. Henderson, San Diego, CA (US); Shiqun Gu, San Diego, CA (US)

(73) Assignee: QUALCOMM Incorporated, San Diego, CA (US)

(21) Appl. No.: 13/783,124

(22) Filed: Mar. 1, 2013

Related U.S. Application Data
(60) Provisional application No. 61/764,289, filed on Feb. 13, 2013.

(51) Int. Cl. H01L 23/34; H01L 21/50

(52) U.S. Cl. CPC H01L 23/34; H01L 21/50
USPC 257/712; 438/122

(57) ABSTRACT

Some implementations provide an apparatus that includes a package substrate, a first die coupled to the package substrate, and a second die coupled to the first die. The die package also includes a heat spreader coupled to the second die, the heat spreader configured to (i) dissipate heat from the second die, and (ii) provide an electrical path for a power signal to the second die. In some implementations, the die package also includes a molding surrounding the first die and the second die. The die package also includes several through mold vias (TMVs) coupled to the heat spreader. The TMVs are configured to provide an electrical path for the power signal to the second die through the heat spreader. In some implementations, the TMVs traverse the molding.

The present application claims priority to U.S. Provisional Application No. 61/764,289 entitled “Power Distribution and Thermal Solution for Direct Stacked Integrated Circuits”, filed Feb. 13, 2013, which is hereby expressly incorporated by reference herein.

### BACKGROUND

1. Field

Various features relate to power distribution and thermal solution for direct stacked integrated circuits (ICs).

2. Background

Current die packages that include stacked dies (e.g., a top die and a bottom die) usually provide a power supply connection to the top die through an electrical path that traverses the bottom die. FIG. 1 illustrates an example of a die package with such a design. As shown in FIG. 1, the die package 100 includes a package substrate 102, a first die 104, a second die 106, a molding 108, a heat spreader 110. As shown in FIG. 1, the first die 104 is coupled and positioned above (e.g., on top of) the package substrate 102. The first die 104 includes an active region 112 and a back-side region 114. The active region 112 includes a substrate. The back-side region 114 includes metal layers and dielectric layers. As further shown in FIG. 1, the second die 106 is positioned above (e.g., on top of) the first die 104. The second die 106 includes an active region 116 and a back-side region 118. The active region 116 of the die includes a substrate. The back-side region 118 includes metal layers and dielectric layers.

The first die 104 and the second die 106 are surrounded by a molding material 108. In some implementations, the molding material 108 encapsulates the first die 104 and the second die 106 and provides a protective layer for the first die 104 and the second die 106. As further shown in FIG. 1, the second die 106 generates heat which is dissipated through the heat spreader 110.

FIG. 1 also illustrates that power for the second die 106 is provided through vias 120-122. The vias 120-122 are power/ground vias 120-122. As shown in FIG. 1, the vias 120-122 traverse the package substrate 102 and the first die 104 to couple to the second die 106. The problem with this power distribution design is that there is high resistance/impedance in the electrical path of the of power signal to the second die 106 due to the fact that power to the second die 106 traverses the first die 104.

Therefore, there is a need for an improved power distribution network that has better impedance characteristic than current die package designs.

### SUMMARY

Various features relate to power distribution and thermal solution for direct stacked integrated circuits (ICs).

A first example provides an apparatus that includes a package substrate, a first die coupled to the package substrate, and a second die coupled to the first die. The die package also includes a heat spreader coupled to the second die, the heat spreader configured to (i) dissipate heat from the second die, and (ii) provide an electrical path for a power signal to the second die.

According to one aspect, the apparatus includes a molding surrounding the first die and the second die. The apparatus also includes several through mold vias (TMVs) coupled to the heat spreader. The TMVs are configured to provide an electrical path for the power signal to the second die through the heat spreader. In some implementations, the TMVs traverse the molding. In some implementations, the heat spreader is above the molding surrounding the first die and the second die.

According to an aspect, the apparatus includes a wire bond configured to provide an electrical path for the power signal to the second die through the heat spreader. In some implementations, the heat spreader is a patterned heat spreader.

According to one aspect, the heat spreader is part of a power distribution network that provides power to the second die. In some implementations, the power distribution network is configured to bypass going through the first die when providing power to the second die.

According to an aspect, the second die includes a via structure comprising a first via and a second via. The first via includes a first width. The second via includes a second width. The first width is greater than the second width. In some implementations, the first via is coupled to the heat spreader and the second via is coupled to the first via.

According to one aspect, the heat spreader is a patterned heat spreader.

According to an aspect, the apparatus is incorporated into at least one of a music player, a video player, an entertainment unit, a navigation device, a communications device, a mobile phone, a smartphone, a personal digital assistant, a fixed location terminal, a tablet computer, and/or a laptop computer.

A second example provides an apparatus that includes a package substrate, a first die coupled to the package substrate, a second die coupled to the first die, and a heat dissipating means for heat dissipation and power distribution of the second die.

According to an aspect, the apparatus further includes a molding surrounding the first die and the second die. In some implementations, the heat dissipating means comprises a heat spreader configured to (i) dissipate heat from the second die, and (ii) provide an electrical path for a power signal to the second die. In some implementations, the heat dissipating means further includes several through mold vias (TMVs) coupled to the heat spreader. The several TMVs configured to provide an electrical path for the power signal to the second die through the heat spreader.

According to one aspect, the heat dissipating means is above the molding surrounding the first die and the second die.

According to an aspect, the apparatus further includes a wire bond configured to provide an electrical path for the power signal to the second die through the heat dissipating means.

According to one aspect, the heat dissipating means is part of a power distribution network that provides power to the second die, the power distribution network configured to bypass going through the first die when providing power to the second die.

According to an aspect, the second die comprises a via structure includes a first via and a second via. The first via includes a first width. The second via includes a second width. The first width is greater than the second width. In some implementations, the first via is coupled to the heat dissipating means. The second via is coupled to the first via.

According to one aspect, the heat dissipating means includes a patterned heat spreader.

According to an aspect, the apparatus is incorporated into at least one of a music player, a video player, an entertainment unit, a navigation device, a communications device, a mobile phone, a smartphone, a personal digital assistant, a fixed location terminal, a tablet computer, and/or a laptop computer.

A third example provides a method for providing a package. The method provides a package substrate. The method provides a first die coupled to the package substrate. The method provides a second die coupled to the first die. The method provides a heat spreader coupled to the second die. The heat spreader is configured to (i) dissipate heat from the second die, and (ii) provide an electrical path for a power signal to the second die.

According to an aspect, the method further includes providing a molding surrounding the first die and the second die. The method also includes providing several through mold vias (TMVs) coupled to the heat spreader. The several TMVs is configured to provide an electrical path for the power signal to the second die through the heat spreader. In some implementations, the several TMVs traverse the molding. In some implementations, the heat spreader is above the molding surrounding the first die and the second die.

According to one aspect, the method further includes providing a wire bond configured to provide an electrical path for the power signal to the second die through the heat spreader.

According to an aspect, the heat spreader is part of a power distribution network that provides power to the second die. The power distribution network is configured to bypass going through the first die when providing power to the second die.

According to one aspect, the second die includes a via structure comprising a first via and a second via. The first via includes a first width. The second via includes a second width. The first width is greater than the second width. In some implementations, the first via is coupled to the heat spreader and the second via is coupled to the first via.

According to an aspect, the heat spreader is a patterned heat spreader.

According to one aspect, the method further includes incorporating the package into at least one of a music player, a video player, an entertainment unit, a navigation device, a communications device, a mobile phone, a smartphone, a personal digital assistant, a fixed location terminal, a tablet computer, and/or a laptop computer.

### DRAWINGS

Various features, nature and advantages may become apparent from the detailed description set forth below when taken in conjunction with the drawings in which like reference characters identify correspondingly throughout.

FIG. 1 illustrates a conventional die package.

FIG. 2 illustrates a die package with a heat spreader integrated in a power distribution network of the die package.

FIG. 3 illustrates another die package with a heat spreader integrated in a power distribution network of the die package.

FIG. 4 illustrates another die package with a heat spreader integrated in a power distribution network of the die package.

FIG. 5 illustrates a flow diagram of a method for manufacturing a die package with a heat spreader integrated in a power distribution network for the die package.

FIGS. 6A-6C illustrate a sequence for manufacturing a die package with a heat spreader integrated in a power distribution network for the die package.

FIG. 7 illustrates another flow diagram of a method for manufacturing a die package with a heat spreader integrated in a power distribution network for the die package.

FIGS. 8A-8D illustrate another sequence for manufacturing a die package with a heat spreader integrated in a power distribution network for the die package.

FIG. 9 illustrates various electronic devices that may be integrated with any of the aforementioned integrated circuit, die or package.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

### Overview

Several novel features pertain to a die package/apparatus that includes a package substrate, a first die coupled to the package substrate, and a second die coupled to the first die. The die package also includes a heat spreader coupled to the second die. The heat spreader is configured to (i) dissipate heat from the second die, and (ii) provide an electrical path for a power signal to the second die. In some implementations, the die package also includes a molding surrounding the first die and the second die. The die package also includes several through mold vias (TMVs) coupled to the heat spreader. The TMVs are configured to provide an electrical path for the power signal to the second die through the heat spreader. In some implementations, the heat spreader is part of a power distribution network for the second die. In some implementations, the die package also includes a wire bond configured to provide an electrical path for the power signal to the second die through the heat spreader.

Exemplary Die Package with Heat Spreader for Power Distribution

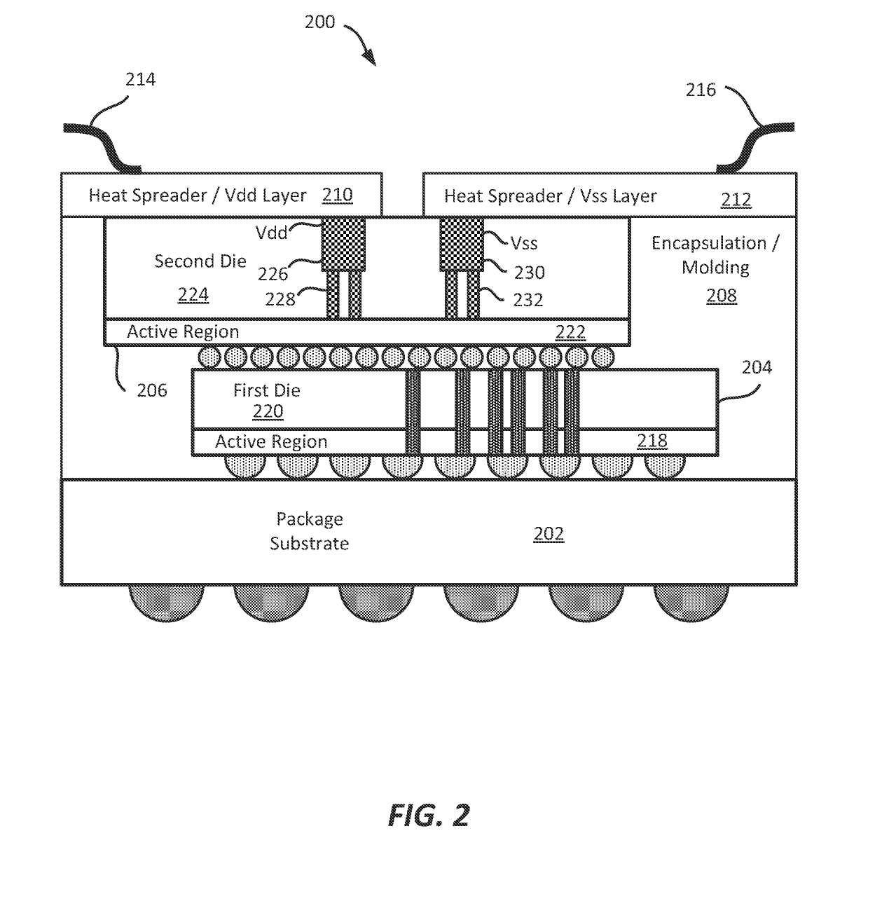

FIG. 2 illustrates a die package 200 (e.g., apparatus) that includes a package substrate 202, a first die 204, a second die 206, a molding 208, a first heat spreader 210, a second heat spreader 212, a first wire bond 214, and a second wire bond 216. As shown in FIG. 2, the first die 204 is coupled and positioned above (e.g., on top of) the package substrate 202. The first die 204 includes an active region 218 and a back-side region 220 (e.g., die substrate). The active region 218 of the die may be referred to as a top region of a die. The back-side region 220 includes metal layers and dielectric layers.

As further shown in FIG. 2, the second die 206 is positioned above (e.g., on top of) the first die 204. The second die 206 includes an active region 222 and a back-side region 224 (e.g., die substrate). The active region 222 of the die may be referred to as a top region of a die. The back-side region 224 includes metal layers and dielectric layers. The second die 206 also includes a first set of vias 226-228 and a second set of vias 230-232. The first set of vias 226-228 may define a first via structure (e.g., first hybrid via) that provides an electrical path for a power signal (e.g., V_{dd}) to the second die 206. The first set of vias 226-228 includes a first via 226 that has a first width/diameter, and a third via 228 that has third width/diameter. The first width/diameter may be greater than the third width/diameter. The second set of vias 230-232 may define a second via structure (e.g., second hybrid via) that provides an electrical path for a ground signal (e.g., Vₛₛ) from the second die 206. The second set of vias 230-232 includes a second via 230 that has a second width/diameter, and a fourth via 232 that has a fourth width/diameter. The second width/diameter may be greater than the fourth diameter. In some implementations, the different widths/diameters of the vias provide strength, mechanical stability/rigidity of the coupling between the heat spreader and the second die. In addition, the use of larger vias improves the thermal conductivity of the second die 206 in some implementations. That is, the larger vias improve and/or increase the amount of heat that is dissipated from the second die 206 in some implementations.

The first die 204 and the second die 206 are surrounded by the molding 208 (e.g., mold material). In some implementations, the molding 208 encapsulates the first die 204 and the second die 206 and provides a protective layer for the first die 204 and the second die 206. Different implementations may use different molding configuration and/or materials. For example, the molding 208 may be configured as walls that surround the first and second dies 204-206.

In some implementations, the second die 206 is a high power integrated circuit that generates a lot of heat. As such, the second die 206 is positioned at the top of the package so that heat from the second die 206 can dissipate more efficiently. To further increase/enhance heat dissipation from the second die 206, heat spreaders 210-212 are coupled to the second die 206. The heat spreaders 210-212 are configured to dissipate heat from the second die 206 to an external environment. In some implementations, the heat spreaders 210-212 are configured in such a way that heat from the second die 206 is mostly (e.g., majority) or substantially dissipated from the heat spreaders 210-212. The heat spreaders 210-212 may be made with a material that has high thermal conductivity. The heat spreaders 210-212 may be made of a copper material in some implementations. In some implementations, the heat spreaders 210-212 may include at least one metal layer of the back-side region 224 of the second die 206.

In addition, the heat spreaders 210-212 may provide an electrical path for power signal to/from wire bonds (e.g., wire bonds 214-216). In some implementations, the heat spreaders 210-212 may be part/integrated in a power distribution network that provides power to the second die 206 (e.g., provides power to components in the active region 222). In some implementations, a power distribution network is a set of components coupled together that allow power to be distributed to/from a die, package substrate and/or integrated circuit (IC). For example, a power distribution network may provide power from a package substrate to a second die. As shown in FIG. 2, the wire bond 214 is coupled to the heat spreader 210, which is coupled to the first set of vias 226-228. The heat spreader 210 is configured to provide an electrical path for a power signal to the second die 206. Thus, in the configuration shown in FIG. 2, a power signal may travel from the wire bond 214, through the heat spreader 210, and the first set of vias 226-228. In some implementations, the wire bond 214 is coupled to the package substrate 202. FIG. 2 also includes the wire bond 216 coupled to the heat spreader 212, which is coupled to the second set of vias 230-232. In this configuration, a power signal may travel from the second set of vias 230-232, through the heat spreader 212, and the wire bond 216. In some implementations, the wire bond 216 is coupled to the package substrate 202. In some implementations, a power distribution network for the second die 206 may include the first set of vias 226-228, the second set of vias 230-232, the first heat spreader 210, the second heat spreader 212, the first wire bond 214, and the second wire bond 216. As described above, the power distribution network may provide power to components (e.g., active components) of the active region 222 of the second die 206.

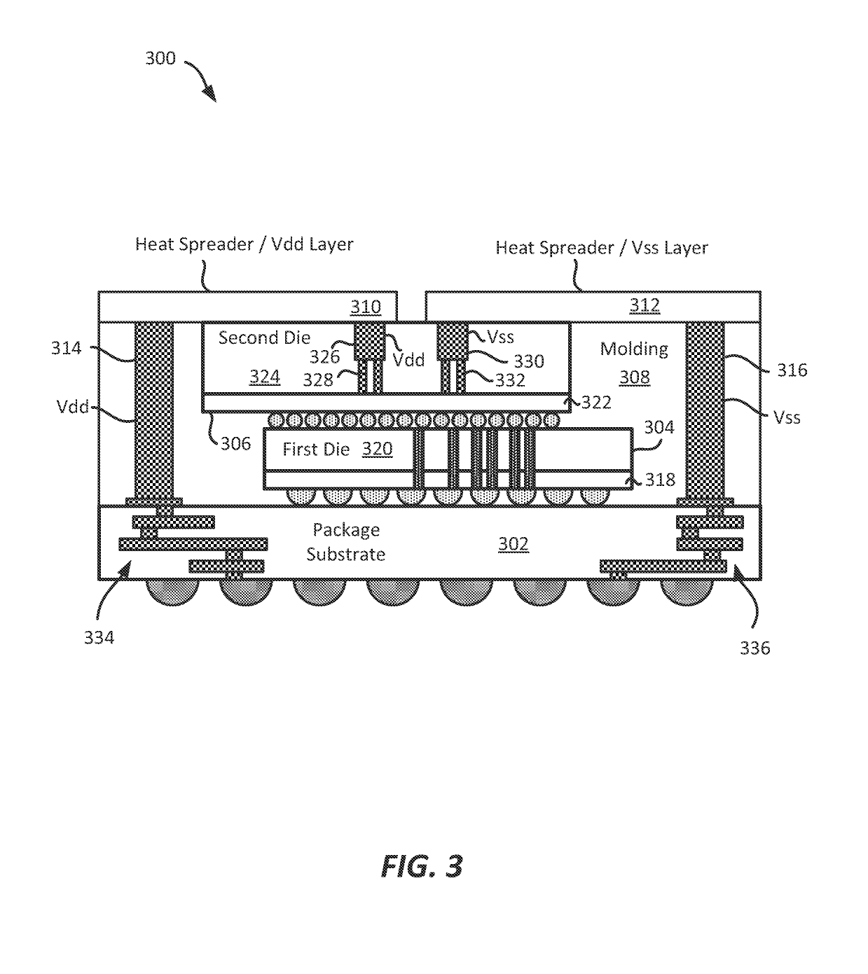

In some implementations, power may be provided to the second die through a connection other than a wire bond. FIG. 3 illustrates a configuration of a die package that includes a heat spreader that is configured to provide an electrical path for a power signal to a die. FIG. 3 is similar to FIG. 2, except that the power to the top die (e.g., second die) of a die package is provided using a different path (e.g., using through mold vias). Specifically, FIG. 3 illustrates a die package 300 (e.g., apparatus) that includes a package substrate 302, a first die 304, a second die 306, a molding 308, a first heat spreader 310, a second heat spreader 312, a first through mold via (TMV) 314, and a second through mold via (TMV) 316. As shown in FIG. 3, the package substrate 302 includes a set of power signal interconnects and vias 334-336. These set of power signal interconnects and vias 334-336 may be part of/integrated in a power distribution network.

FIG. 3 also illustrates that the first die 304 is coupled and positioned above (e.g., on top of) the package substrate 302. The first die 304 includes an active region 318 and a back-side region 320 (e.g., die substrate). The active region 318 of the die may be referred to as a top region of a die. The back-side region 320 includes metal layers and dielectric layers.

As further shown in FIG. 3, the second die 306 is positioned above (e.g., on top of) the first die 304. The second die 306 includes an active region 322 and a back-side region 324 (e.g., die substrate). The active region 322 of the die may be referred to as a top region of a die. The back-side region 324 includes metal layers and dielectric layers. The second die 306 also includes a first set of vias 326-328 and a second set of vias 330-332. The first set of vias 326-328 may define a first via structure (e.g., first hybrid via) that provides an electrical path for a power signal (e.g., V_{dd}) to the second die 306. The first set of vias 326-328 includes a first via 326 that has a first width/diameter, and a third via 328 that has third width/diameter. The first width/diameter may be greater than the third width/diameter. The second set of vias 330-332 may define a second via structure (e.g., second hybrid via) that provides an electrical path for a ground signal (e.g., Vₛₛ) from the second die 306. The second set of vias 330-332 includes a second via 330 that has a second width/diameter, and a fourth via 332 that has a fourth width/diameter. The second width/diameter may be greater than the fourth diameter. In some implementations, the different widths/diameters of the vias provide strength, mechanical stability/rigidity of the coupling between the heat spreader(s) and the second die 306. In addition, the use of larger vias improve the thermal conductivity of the second die 306 in some implementations. That is, the larger vias improve and/or increase the amount of heat that is dissipated from the second die 306 in some implementations.

The first die 304 and the second die 306 are surrounded by a molding 308 (e.g., mold material). In some implementations, the molding 308 encapsulates the first die 304 and the second die 306 and provides a protective layer for the first die 304 and the second die 306. Different implementations may use different molding configuration and/or materials. For example, the molding 308 may be configured as walls that surround the first and second dies 304-306.

The molding 308 also includes the first TMV 314 and the second TMV 316. The first TMV 314 traverses the molding 308 and is configured to provide an electrical path for a power signal (e.g., V_{dd}) to the second die 306. The second TMV 316 traverses the molding 308 (e.g., traverse the molding wall) and is configured to provide an electrical path for a power signal (e.g., Vₛₛ) from the second die 306.

In some implementations, the second die 306 is a high power integrated circuit that generates a lot of heat. As such, the second die 306 is positioned at the top of the package so that heat from the second die 306 can dissipate more efficiently. To further increase/enhance heat dissipation from the second die 306, heat spreaders 310-312 are coupled to the second die 306. The heat spreaders 310-312 are configured to dissipate heat from the second die 306 to an external environment. In some implementations, the heat spreaders 310-312 are configured in such a way that heat from the second die is mostly (e.g., majority) or substantially dissipated from the heat spreaders 310-312. The heat spreaders 310-312 may be made of a copper material. In some implementations, the heat spreaders 310-312 may include at least one metal layer of the back-side region 324 of the second die 306. In addition, some of the heat may also dissipate from the TMVs 314-316. In some implementations, heat from the second die 306 is mostly (e.g., majority) or substantially dissipated from the heat spreaders 310-312 and TMVs 314-316.

In addition, the heat spreaders 310-212 may provide an electrical path for power signal to/from through mold vias (TMVs) (e.g., TMVs 314-316). As shown in FIG. 3, the TMV 314 is coupled to the heat spreader 310, which is coupled to the first set of vias 326-328. The heat spreader 310 is configured to provide an electrical path for a power signal to the second die 306. Thus, in the configuration shown in FIG. 3, a power signal may travel from the TMV 314, through the heat spreader 310, and the first set of vias 326-328. In some implementations, the power signal is provided to components (e.g., active components) of the active region 322 of the second die 306. FIG. 3 also illustrates the wire bond 316 being coupled to the heat spreader 312, which is coupled to the second set of vias 330-332. In this configuration, a power signal may travel from the second set of vias 330-332, through the heat spreader 312, and the wire bond 316. In some implementations, the power signal is provided to components (e.g., active components) of the active region 322 of the second die 306. In some implementations, a power distribution network for the second die 306 may include the first set of vias 326-328, the second set of vias 330-332, the first heat spreader 310, the second heat spreader 312, the first TMV 314, and the second TMV 316. The power distribution network may also includes the set of power signal interconnects and vias 334-336. As described above, the power distribution network may provide power to components (e.g., active components) of the active region 322 of the second die 306.

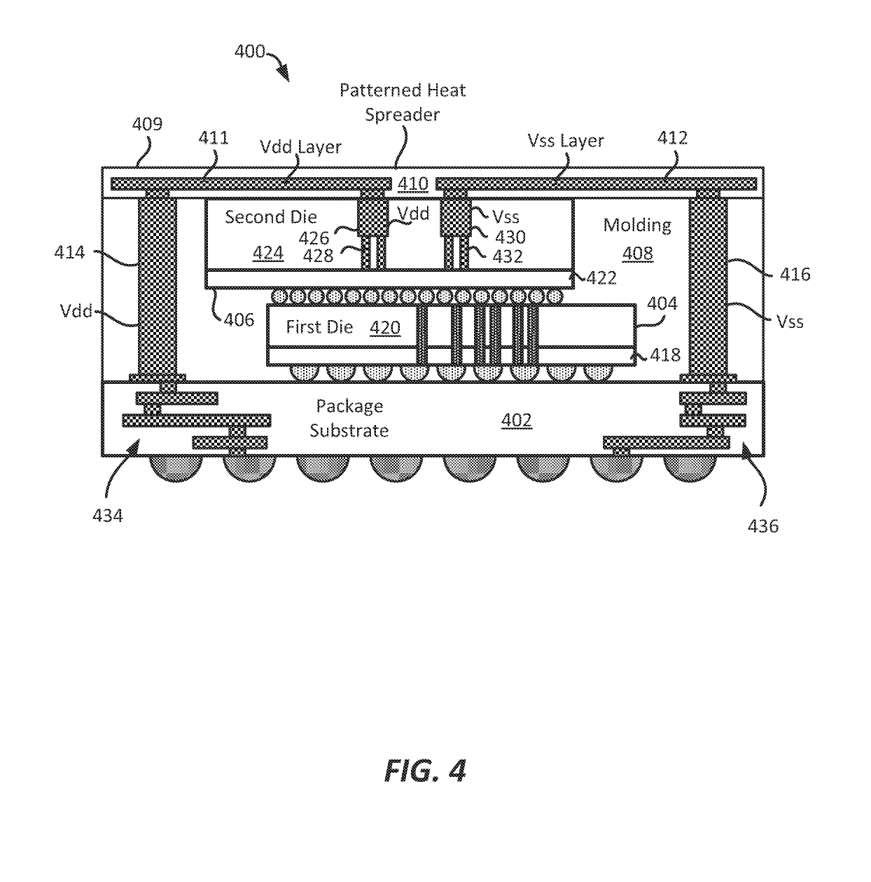

In some implementations, the heat spreaders may have a different design and configuration. FIG. 4 illustrates an example of a die package with a different configuration of a heat spreader. Specifically, FIG. 4 illustrates an example of a die package 400 with a patterned heat spreader 409. As shown in FIG. 4, the patterned heat spreader 409 includes an insulator layer 410, a first connection layer 411 and a second connection layer 412. The first connection layer 411 is configured to provide an electrical path for a power signal to the second die 406. The first connection layer 411 may include several traces, interconnects, and/or vias. The second connection layer 412 is configured to provide an electrical path for a power signal from the second die 406. The second connection layer 412 may include several traces, interconnects and/or vias. In some implementations, a power distribution network for the second die 406 may include the first set of vias 426-428, the second set of vias 430-432, the first connection layer 411, the second connection layer 412, the first TMV 414, and the second TMV 416. In some implementations, the first connection layer 411 and/or the second connection layer 412 may be a metal layer (e.g., copper, aluminum). In some implementations, the traces and/or interconnects of the first and second connection layers 411-412 may be metal traces and/or metal interconnects. In some implementations, the material used for the insulator layer 410 may be polyimide. In such a configuration, the heat may dissipate from the second die 406 through the power distribution network (e.g., through the vias 426-432, the connection layers 411-412, and/or TMVs 414-416). The power distribution network may also includes the set of power signal interconnects and vias 434-436. The power distribution network may provide power to components (e.g., active components) of the active region 422 of the second die 406.

FIGS. 2-4 illustrate several examples of die packages that leverage heat spreaders as an electrical path for power signal to a top die in a die package. These heat spreaders are configured in such a way as to allow power signals to bypass going through another die (e.g., first die) in the die package. These heat spreaders are part of a power distribution network for a second die in some implementations. Thus, these heat spreaders provide dual functionality, namely, these heat spreaders are configured to provide heat dissipation and an electrical path for power signals (e.g., electrical path to/from the second die). In some implementations of the die packages of FIGS. 2-4, data signals to the second die (e.g., second dies 206, 306, 406) may be provided through the first die (e.g., first dies 204, 304, 404) of a package (e.g., by using through substrate vias in the first die). That is, in some implementations, data signals to components (e.g., active components) of the active region of the second die may travel through the first die. It should also be noted that the novel power distribution network described may be applied to a die package that includes more than two dies. Moreover, FIGS. 2-4 illustrate a second die being offset from the first die in the die package. However, in some implementations, the second die may be aligned with the first die in the die package. It should further be noted that different implementations may use different via structures (e.g., hybrid vias). For example, in some implementations, via structures (e.g., hybrid vias) may include more than two vias (e.g., may have 3, 4, 5 or more vias in series). These vias in series may have different widths/diameters in different implementations.

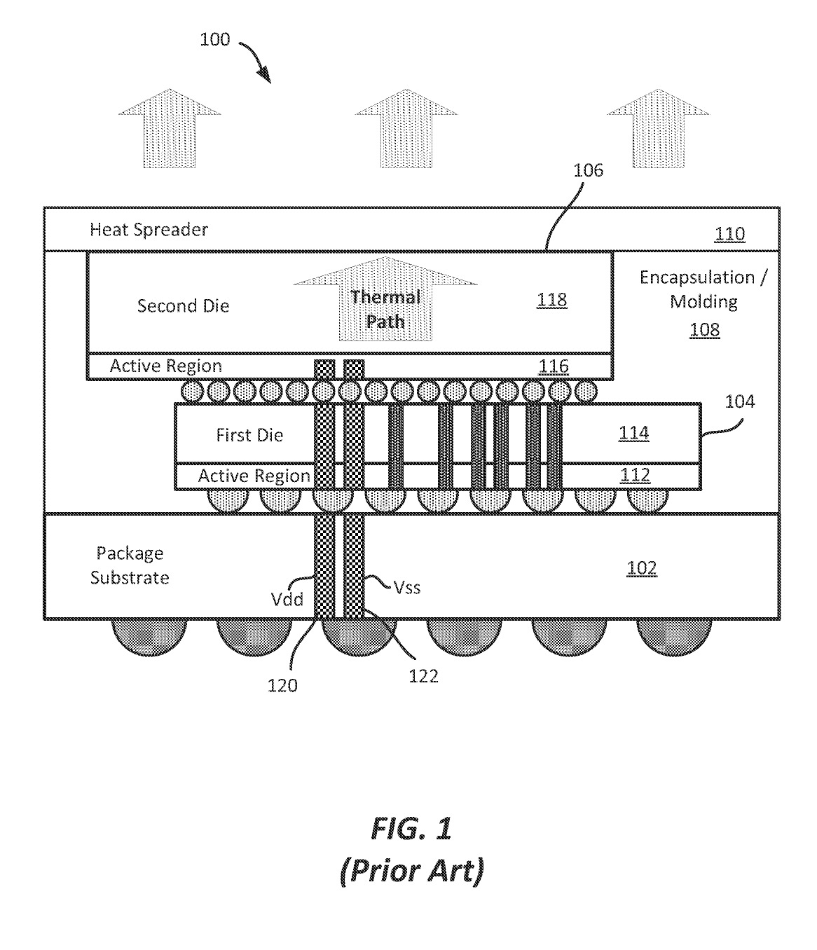

In some implementations, the resistance and/or impedance of the novel power distribution network in the die packages shown in FIGS. 2-4 is less or substantially less than the resistance and/or impedance of the power distribution network in the conventional die package shown in FIG. 1. In some implementations, the resistance in the novel power distribution network may be about or at least 50 percent less than the conventional power distribution network (e.g., 50% drop in resistance from package substrate to the active region of the second die). The lower resistance and/or impedance of the novel power distribution network allows for better electrical performance and/or lower power consumption of the die package in some implementations.

Having described various examples of a die package with heat spreaders configured to provide power distribution for a die, a method for providing/manufacturing a die package that includes heat spreaders will now be described below.

### Exemplary Method for Providing/Manufacturing a Die Package That Includes a Heat Spreader Configured to Provide Power Distribution

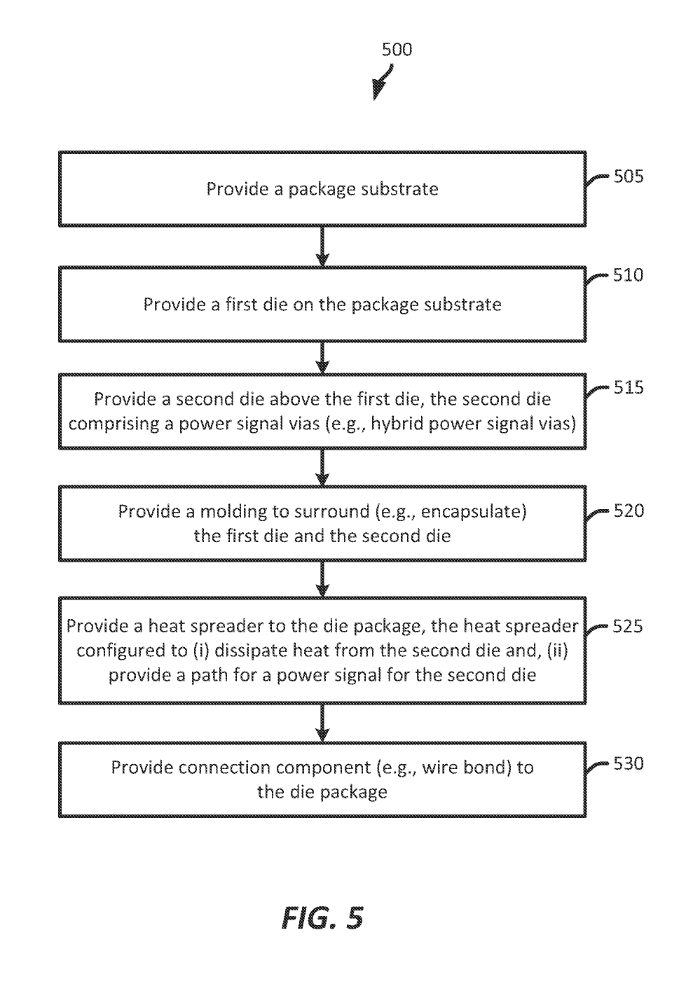

FIG. 5 illustrates a flow diagram of a method for providing/manufacturing a die package (e.g., apparatus) that includes a heat spreader configured to provide power distribution. The method of FIG. 5 will be described with reference to the die package of FIG. 2. However, the method of FIG. 5 may be applied to other die packages.

The method starts by providing (at 505) a package substrate. In some implementations, providing (at 505) the die package substrate includes manufacturing a package substrate. The package substrate may include power signal interconnects and vias. In some implementations, these power signal interconnects and vias may be part of/integrated in a power distribution network that provides power to one or more dies in a die package.

The method provides (at 510) a first die on the package substrate. In some implementations, providing (at 510) the first die may include manufacturing the first die and/or coupling the first die to the package substrate. The first die may include through substrate vias (TSVs). The first die may be coupled to the package substrate through a set of solder balls and/or bumps (e.g., flip clip bumps). Examples of a first die include the first dies 204, 304 and 404 of FIGS. 2-4.

The method provides (at 515) a second die above the first die. In some implementations, providing (at 515) the second die includes manufacturing the second die and/or coupling the second die above the first die. The second die may include power signal vias (e.g., hybrid power signal vias) that traverse metal and dielectrics portions of the second die. These power signal vias may include a first vias that has a first width that is coupled to a second via that has a second width. In some implementations, the second width is less than the first width. Examples of a second die include the second dies 206, 306 and 406 of FIGS. 2-4. These via structures (e.g., hybrid vias) may be coupled to components (e.g., active components) of the active region of the second die in some implementations.

The method provides (at 520) a molding to surround the first die and the second die. In some implementations, the molding encapsulates the first die and the second die and provides a protective layer for the first die and the second die. In some implementations, the molding is configured as a wall that surrounds the first and second dies.

The method further provides (at 525) a heat spreader to the die package. In some implementations, the heat spreader is coupled to a top portion of the die package (e.g., above the molding of the die package). The heat spreader may be coupled to the second die. The heat spreader is configured to (i) dissipate heat from the second die, and (ii) provide an electrical path for a power signal for the second die. In some implementations, the heat spreader is configured in such a way that heat from the second die is mostly (e.g., majority) or substantially dissipated from the heat spreader. The heat spreader may be part of/integrated in a power distribution network that provides power to the second die (e.g., provides power to components of an active region of the second die). The heat spreader may be made of a copper material. Different implementations may use different heat spreaders. In some implementations, multiple heat spreaders are used. In some implementations, a patterned heat spreader may be used, such as the one described in FIG. 4.

The method also provides (at 530) a connection component (e.g., wire bond) to the die package. In some implementations, providing (at 530) the connection component includes manufacturing a wire bond and coupling the wire bond to the heat spreader. In some implementations, one end of the wire bond is coupled to the heat spreader while the other end of the wire bond is coupled to the package substrate.

Having described a method for providing a die package that includes a heat spreader configured to provide power distribution, a sequence for providing a die package that includes a heat spreader configured to provide power distribution will now be described below.

### Exemplary Sequence for Providing/Manufacturing a Die Package That Includes a Heat Spreader Configured to Provide Power Distribution

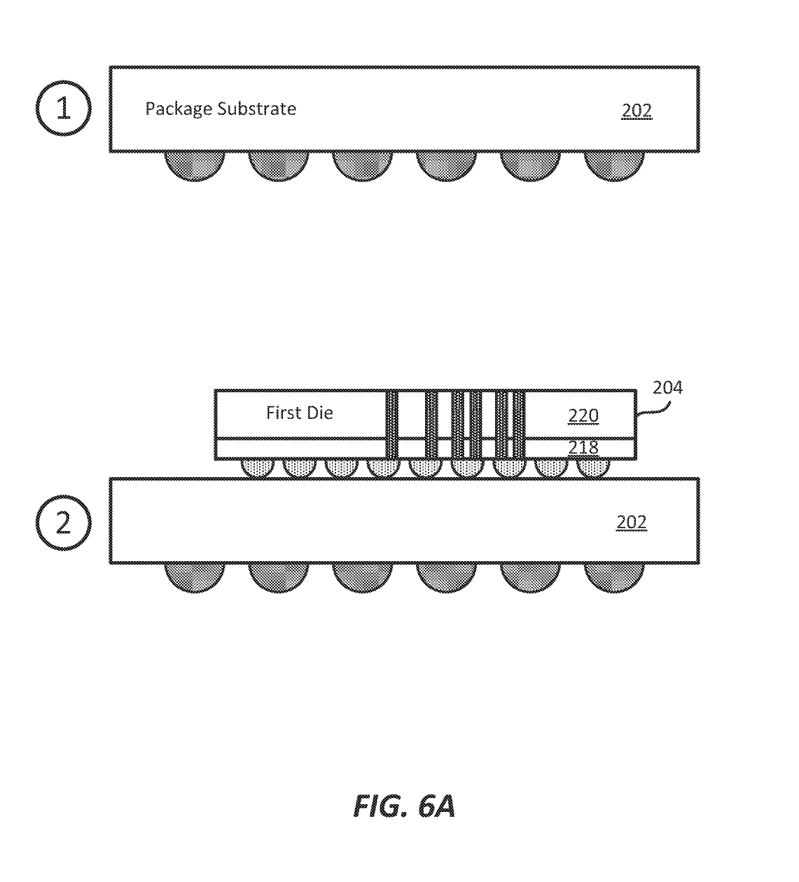

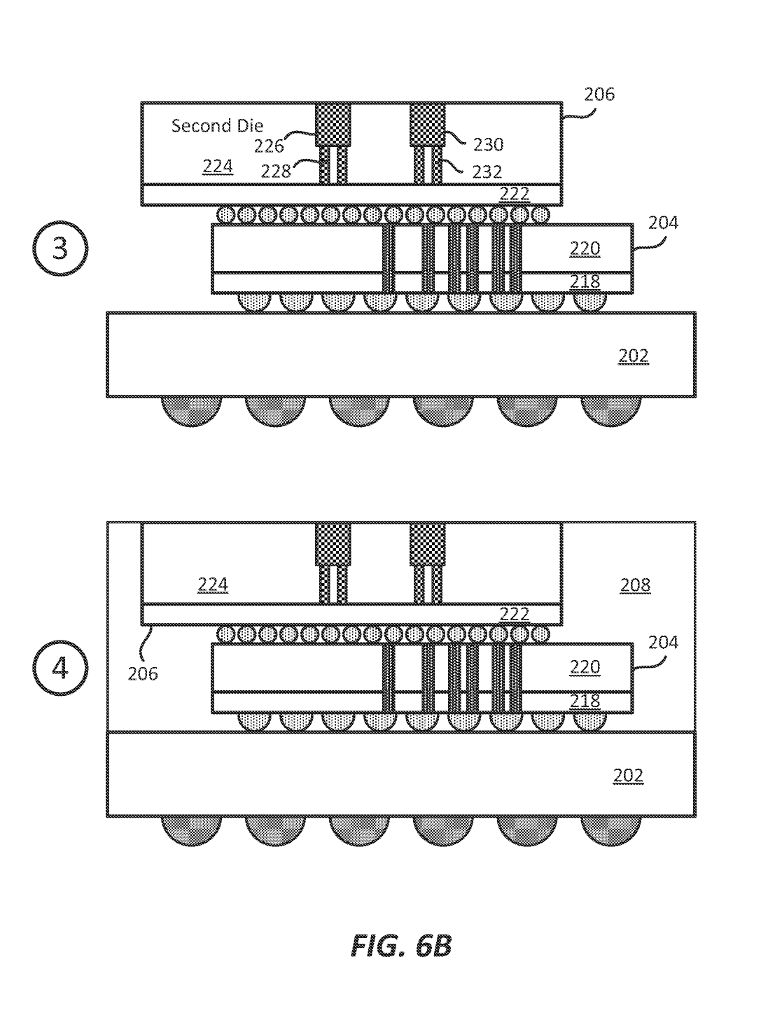

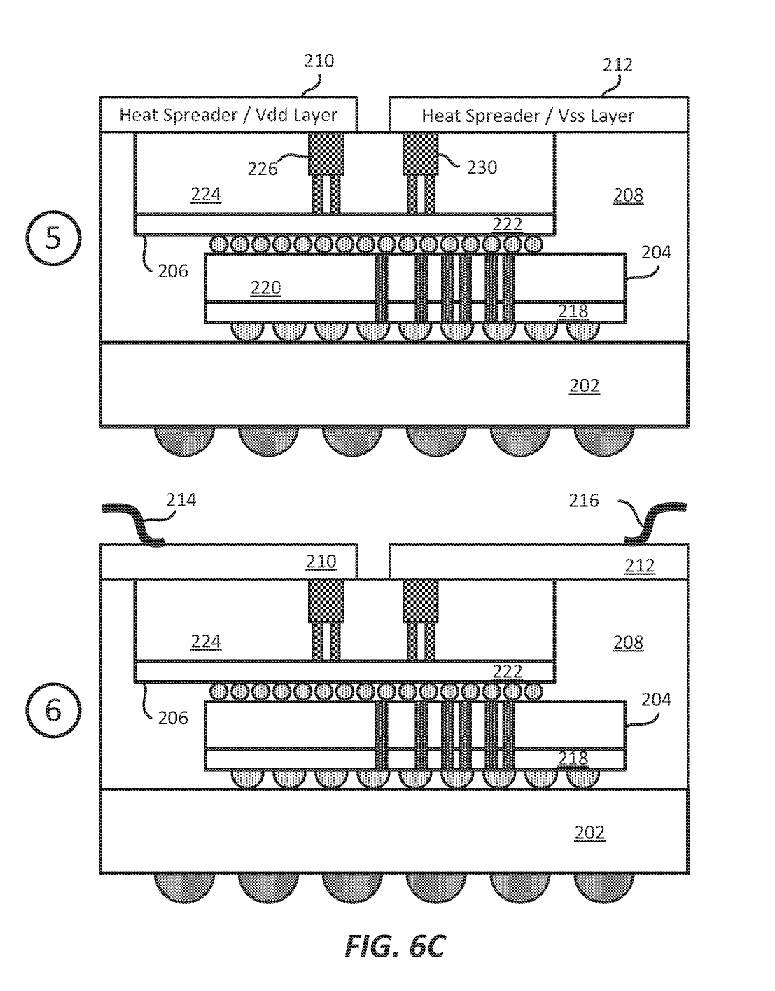

FIGS. 6A-6C illustrates a sequence for providing/manufacturing a die package (e.g., apparatus) that includes a heat spreader configured to provide power distribution. The sequence of FIGS. 6A-6C will be described with reference to the die package of FIG. 2. However, the sequence of FIGS. 6A-6C may be applied to other die packages.

As shown in FIG. 6A, the sequence starts at stage 1 with a package substrate 202. At stage 2, a first die 204 is coupled to the package substrate 202. The first die 204 is coupled to the package substrate 202 by a set of solder and/or bumps (e.g., flip chip bumps). The first die 204 includes several through substrate vias (TSVs) that traverse an active region 218 and a back-side region 220 of the first die. The active region 218 may include a substrate. The back-side region 220 may include metal and dielectric layers.

As shown in FIG. 6B, at stage 3, a second die 206 is coupled to the first die 204. The second die 206 is positioned above the first die 204. The second die 206 is coupled to the first die 204 by a set of solder and/or bumps. The second die 206 includes an active region 222 and a back-side region 224. The active region 222 of the second die 206 is coupled to the back-side region 220 of the first die 204. The second die 206 also includes a set of power signal vias (e.g., vias 226-232).

At stage 4, a molding 208 surrounding the first die 204 and the second die 206 is provided. The molding 208 encapsulates the first die 204 and the second die 206, and provides a protective layer around the first die 204 and the second die 206. In some implementations, the molding 208 is configured as a wall that surrounds the first and second dies 204-206.

As shown in FIG. 6C, at stage 5, a first heat spreader 210 and a second heat spreader 212 are coupled to the die package. More specifically, the first heat spreader 210 is coupled to the first set of vias 226 of the second die 206 and the second heat spreader 212 is coupled to the second set of vias 230 of the second die 206. The heat spreaders 210-212 are configured to (i) dissipate heat from the second die 206, and (ii) provide an electrical path for a power signal to/from the second die 206 (e.g., provide power signal to/from components of active region of second die). In some implementations, the heat spreaders 210-212 are configured in such a way that heat from the second die is mostly (e.g., majority) or substantially dissipated from the heat spreaders 210-212. In some implementations, the heat spreaders 210-212 are part of/integrated in a power distribution network for the second die 206.

At stage 6, wire bonds 214-216 are coupled to the die package. More specifically, a first wire bond 214 is coupled to the first heat spreader 210 and a second wire bond 216 is coupled to the second heat spreader 212. In some implementations, one end of the first wire bond 214 is coupled to the package substrate 202. Similarly, in some implementations, one end of the second wire bond 216 is coupled to the package substrate 202. In some implementations, the wire bonds 214-216, the heat spreaders 210-212, and the vias 226-232 are part of/integrated in a power distribution network for the second die 206.

It should be noted that the order in which the package substrate, first die, the second die, the molding, the heat spreaders, and the wire bonds provided in FIGS. 5, 6A-6C are merely exemplary. In some implementations, the order can be switched or rearranged.

As described above, in some implementations, a power distribution network may include through mold vias (TMVs). Having described a structure, method and sequence for providing a die package that includes a heat spreader configured to provide power distribution, another method and sequence for providing a die package that includes a heat spreader and TMVs that are configured to provide power distribution will now be described below

### Exemplary Method for Providing/Manufacturing a Die Package That Includes a Heat Spreader and TMVs Configured to Provide Power Distribution

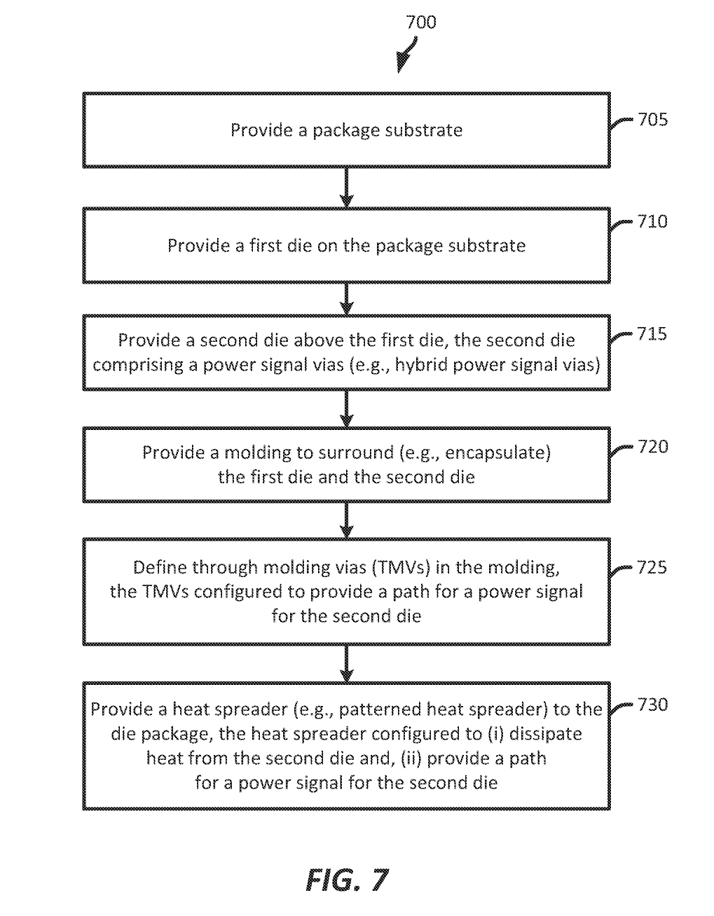

FIG. 7 illustrates a flow diagram of a method for providing/manufacturing a die package (e.g., apparatus) that includes a heat spreader and through mold vias (TMVs) that are configured to provide power distribution. The method starts by providing (at 705) a package substrate. In some implementations, providing (at 705) the die package substrate includes manufacturing a package substrate. The package substrate may include power signal interconnects and vias. In some implementations, these power signal interconnects and vias (e.g., power signal interconnects and vias 434-436) may be part of/integrated in a power distribution network that provides power to one or more dies in a die package.

The method provides (at 710) a first die on the package substrate. In some implementations, providing (at 710) the first die may include manufacturing the first die and/or coupling the first die to the package substrate. The first die may include through substrate vias (TSVs). The first die may be coupled to the package substrate through a set of solder balls and/or bumps (e.g., flip clip bumps). Examples of a first die include the first dies 204, 304 and 404 of FIGS. 2-4.

The method provides (at 715) a second die above the first die. In some implementations, providing (at 715) the second die includes manufacturing the second die and/or coupling the second die above the first die. The second die may include power signal vias (e.g., hybrid power signal vias) that traverse metal and dielectrics portions of the second die. These power signal vias may include a first vias that has a first width that is coupled to a second via that has a second width. In some implementations, the second width is less than the first width. Examples of a second die include the second dies 206, 306 and 406 of FIGS. 2-4. These vias structures (e.g., hybrid vias) may be coupled to components (e.g., active components) of the active region of the second die in some implementations.

The method provides (at 720) a molding to surround the first die and the second die. In some implementations, the molding encapsulates the first die and the second die and provides a protective layer for the first die and the second die. In some implementations, the molding is configured as a wall that surrounds the first and second dies.

The method defines (at 725) through mold vias (TMVs) in the molding. The TMVs are configured to provide an electrical path for a power signal for the second die. The TMVs are part of/integrated in a power distribution network that provides power for the second die in a die package (e.g., provides power to components of an active region of the second die). In some implementations, defining (at 725) the TMVs includes defining (e.g., creating) several cavities in the molding. The cavities may traverse the molding and the package substrate in some implementations. Different implementations may define the cavities differently. In some implementations, the cavities are formed by etching/drilling holes in the molding and the package substrate. The etching/drilling of the cavities may be performed by a laser in some implementations. The cavities may traverse part of or the entire molding and/or package substrate in some implementations. Different implementations may form the cavities in different locations of the die package (e.g., different locations of the molding and/or package substrate). In some implementations, the cavities may be formed so as to surround the dies in the die package. In some implementations, the cavities are formed at the perimeter of the die package (e.g., perimeter of molding and/or package substrate). Once the cavities are defined, the cavities are filled with a conductive material (e.g., copper), which forms the through mold vias (TMVs) in some implementations.

The method further provides (at 730) a heat spreader to the die package. In some implementations, the heat spreader is coupled to a top portion of the die package (e.g., above the molding of the die package). The heat spreader may be coupled to the second die. The heat spreader may also be coupled to the TMVs. The heat spreader is configured to (i) dissipate heat from the second die, and (ii) provide an electrical path for a power signal to/from the second die. In some implementations, the heat spreader is configured in such a way that heat from the second die is mostly (e.g., majority) or substantially dissipated from the heat spreader and/or TMVs. The heat spreader may be part of/integrated in a power distribution network that provides power to the second die (e.g., provides power to components of an active region of the second die). The heat spreader may be made of a copper material. Different implementations may use different heat spreaders. In some implementations, multiple heat spreaders are used. In some implementations, a patterned heat spreader may be used (such as the one described in FIG. 4).

Having described a method for providing a die package that includes a heat spreader configured to provide power distribution, a sequence for providing a die package that includes a heat spreader configured to provide power distribution will now be described below

### Exemplary Sequence for Providing/Manufacturing a Die Package That Includes a Heat Spreader and TMVs Configured to Provide Power Distribution

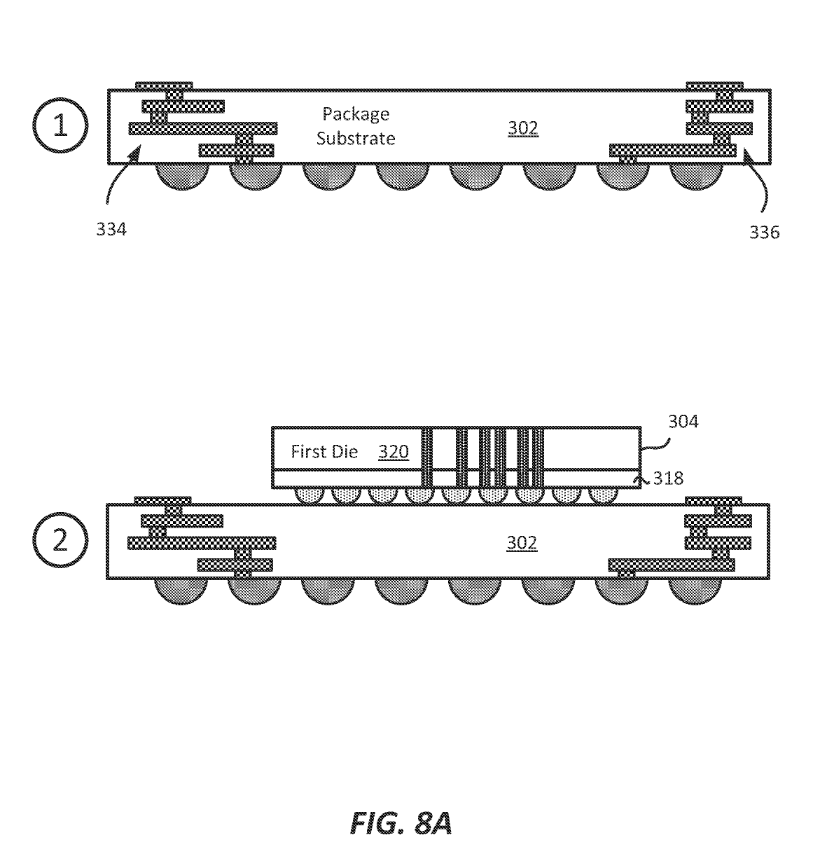

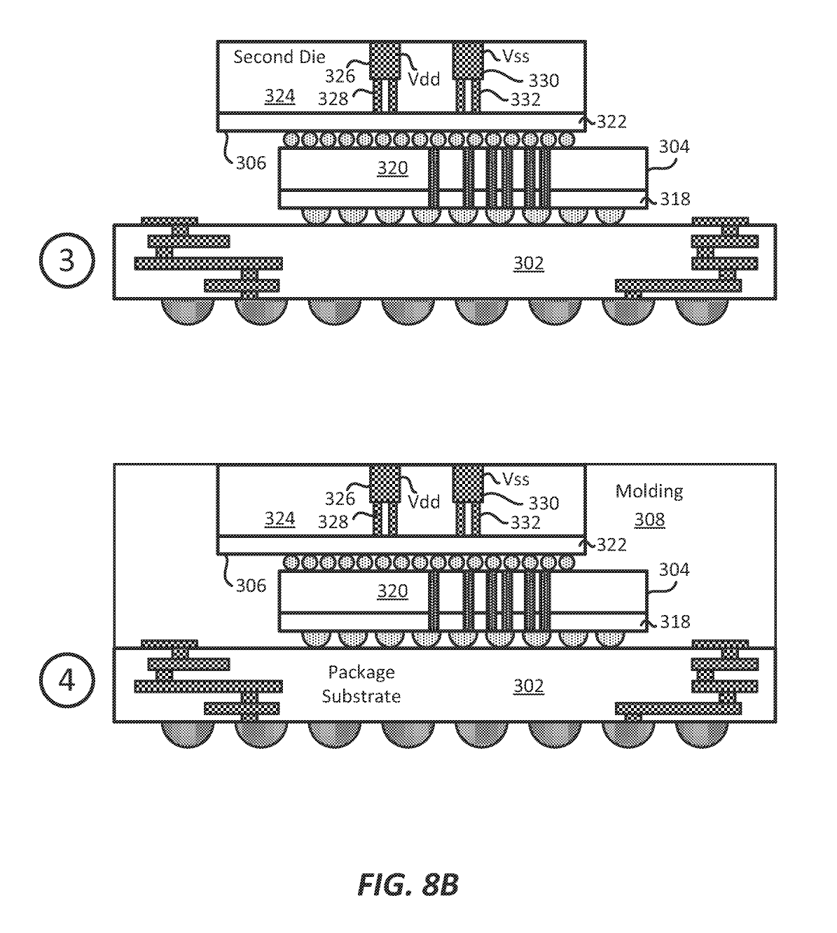

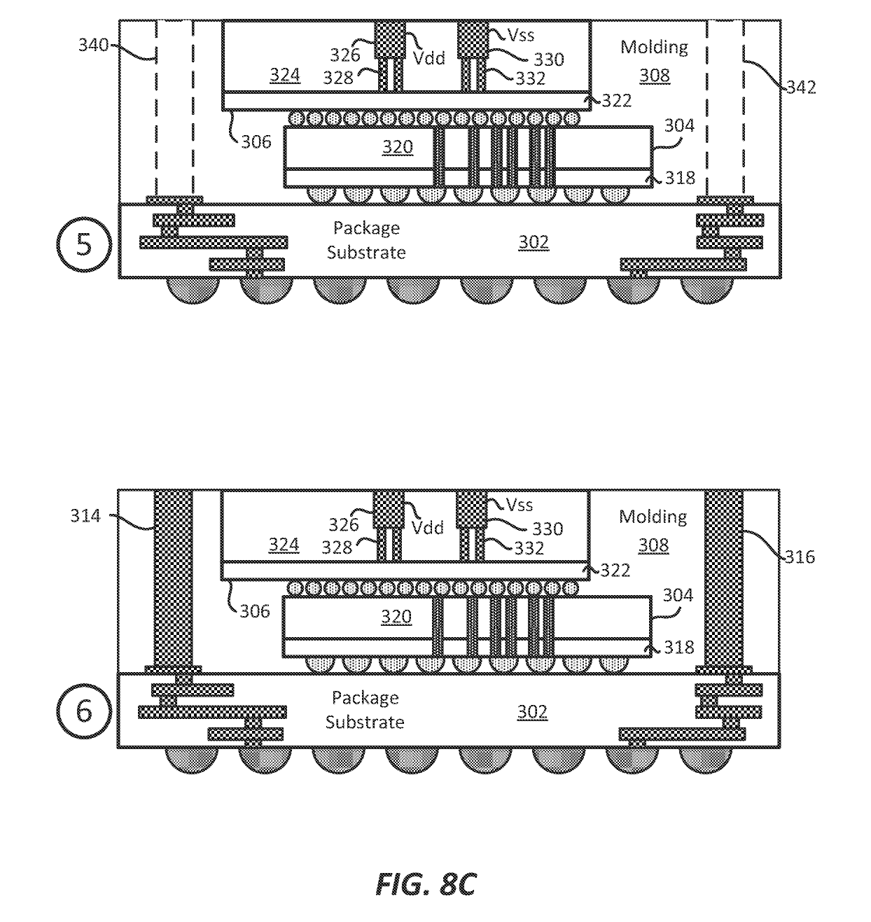

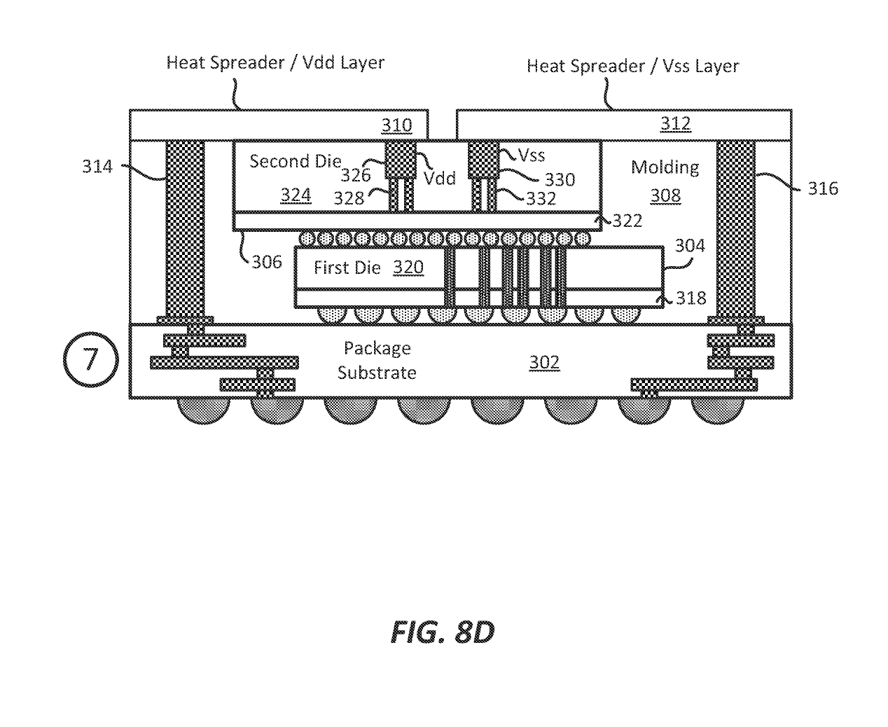

FIGS. 8A-8D illustrates a sequence for providing/manufacturing a die package (e.g., apparatus) that includes a heat spreader and through mold vias (TMVs) that are configured to provide power distribution. The sequence of FIGS. 8A-8D will be described with reference to the die package of FIG. 3. However, the sequence of FIGS. 8A-8D may be applied to other die packages.

As shown in FIG. 8A, the sequence starts at stage 1 with a package substrate 302. The package substrate 302 may include a set of power signal interconnects and vias 334-336. These set of power signal interconnects and vias may be part of/integrated in a power distribution network. At stage 2, a first die 304 is coupled to the package substrate 302. The first die 304 is coupled to the package substrate 302 by a set of solder and/or bumps (e.g., flip chip bumps). The first die 304 includes several through substrate vias (TSVs) that traverse an active region 318 and a back-side region 320 of the first die. The back-side region 320 may include metal and dielectric layers.

As shown in FIG. 8B, at stage 3, a second die 306 is coupled to the first die 304. The second die 306 is positioned above the first die 304. The second die 306 is coupled to the first die 304 by a set of solder and/or bumps. The second die 306 includes an active region 322 and a back-side region 324. The active region 322 of the second die 306 is coupled to the back-side region 320 of the first die 304. The second die 306 also includes a set of power signal vias (e.g., vias 326-332).

At stage 4, a molding 308 (e.g., mold material) surrounding the first die 304 and the second die 306 is provided. The molding 308 encapsulates the first die 304 and the second die 306, and provides a protective layer around the first die 304 and the second die 306. In some implementations, the molding 308 is configured as a wall that surrounds the first and second dies 304-306.

As shown in FIG. 8C, at stage 5, a set of cavities 340-342 are defined (e.g., created, manufactured) in the molding 308. The cavities 340-342 traverse the molding 308. Different implementations may define (e.g., manufacture) the cavities differently. In some implementations, the cavities 340-342 are defined by etching/drilling holes in the molding. The etching/drilling of the cavities 340-342 may be performed by a laser in some implementations. The cavities 340-342 may traverse part of or the entire molding and/or package substrate in some implementations. Different implementations may form the cavities 340-342 in different locations of the die package (e.g., different locations of the molding and/or package substrate). In some implementations, the cavities 340-342 may be formed so as to surround the dies (e.g., first and second dies 304-306) in the die package. In some implementations, the cavities 340-342 are formed at the perimeter of the die package (e.g., perimeter of molding and/or package substrate).

At stage 6, the cavities 340-342 are filed with a conductive material (e.g., copper). Once the cavities 340-342 are filled with a conductive material (e.g., copper), the through mold vias (TMVs) 314-316 are formed in the molding 308. In some implementations, the TMVs 314-316 are part of/integrated in a power distribution network for the second die 306.

As shown in FIG. 8D, at stage 7, a first heat spreader 310 and a second heat spreader 312 are coupled to the die package. More specifically, the first heat spreader 310 is coupled to the first set of vias 326 of the second die 306 and the second heat spreader 312 is coupled to the second set of vias 330 of the second die 306. The heat spreaders 310-312 are configured to (i) dissipate heat from the second die 306, and (ii) provide an electrical path for a power signal to/from the second die 306 (e.g., provide power signal to/from components of active region of the second die). In some implementations, the heat spreaders 310-312 are configured in such a way that heat from the second die is mostly (e.g., majority) or substantially dissipated from the heat spreaders 310-312 and/or TMVs 314-316. In some implementations, the TMVs 314-316, the heat spreaders 310-312, and the vias 326-332 are part of/integrated in a power distribution network for the second die 306. In some implementations, the heat spreader that is provided is a patterned heat spreader.

It should be noted that the order in which the package substrate, first die, the second die, the molding, the TMVs, and the heat spreaders provided in FIGS. 7, 8A-8D are merely exemplary. In some implementations, the order can be switched or rearranged.

### Exemplary Electronic Devices

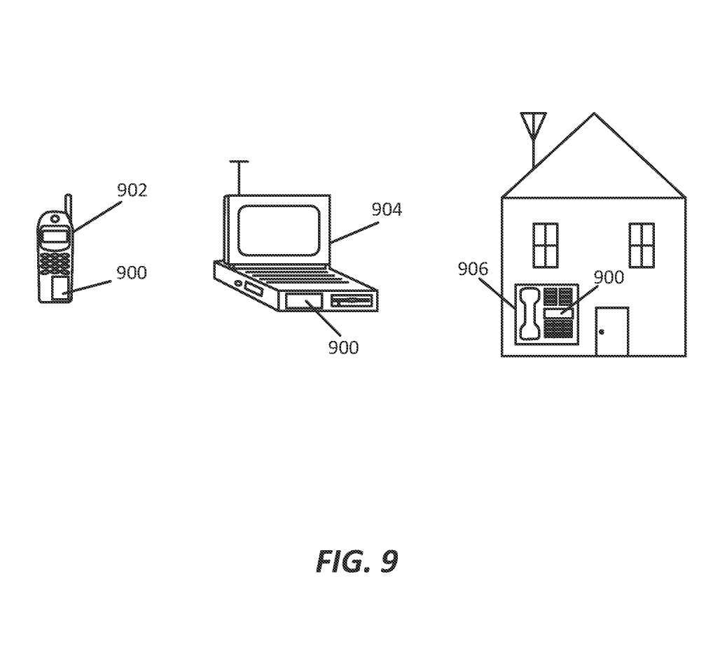

FIG. 9 illustrates various electronic devices that may be integrated with any of the aforementioned integrated circuit, die or package. For example, a mobile telephone 902, a laptop computer 904, and a fixed location terminal 906 may include an integrated circuit (IC) 900 as described herein. The IC 900 may be, for example, any of the integrated circuits, dies or packages described herein. The devices 902, 904, 906 illustrated in FIG. 9 are merely exemplary. Other electronic devices may also feature the IC 900 including, but not limited to, mobile devices, hand-held personal communication systems (PCS) units, portable data units such as personal digital assistants, GPS enabled devices, navigation devices, set top boxes, music players, video players, entertainment units, fixed location data units such as meter reading equipment, communications device, smartphones, tablet computers or any other device that stores or retrieves data or computer instructions, or any combination thereof.

One or more of the components, steps, features, and/or functions illustrated in FIGS. 2, 3, 4, 5, 6A-6C, 7, 8A-8D and/or 9 may be rearranged and/or combined into a single component, step, feature or function or embodied in several components, steps, or functions. Additional elements, components, steps, and/or functions may also be added without departing from the invention.

One or more of the components, steps, features and/or functions illustrated in the FIGs may be rearranged and/or combined into a single component, step, feature or function or embodied in several components, steps, or functions. Additional elements, components, steps, and/or functions may also be added without departing from novel features disclosed herein. The apparatus, devices, and/or components illustrated in the FIGs may be configured to perform one or more of the methods, features, or steps described in the FIGs. The novel algorithms described herein may also be efficiently implemented in software and/or embedded in hardware.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. The term “die package” is used to refer to an integrated circuit wafer that has been encapsulated or packaged or encapsulated.

Also, it is noted that the embodiments may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a function, a procedure, a subroutine, a subprogram, etc. When a process corresponds to a function, its termination corresponds to a return of the function to the calling function or the main function.

Those of skill in the art would further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system.

The various features of the invention described herein can be implemented in different systems without departing from the invention. It should be noted that the foregoing aspects of the disclosure are merely examples and are not to be construed as limiting the invention. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. An apparatus comprising:
a package substrate;
a first die coupled to the package substrate;
a second die coupled to the first die; and
a heat spreader coupled to the second die, the heat spreader configured to (i) dissipate heat from the second die, and (ii) provide an electrical path for a power signal to the second die.

2. The apparatus of claim 1 further comprising:
a molding surrounding the first die and the second die; and
a plurality of through mold vias (TMVs) coupled to the heat spreader, the plurality of TMVs configured to provide an electrical path for the power signal to the second die through the heat spreader.

3. The apparatus of claim 2, wherein the plurality of TMVs traverse the molding.

4. The apparatus of claim 2, wherein the heat spreader is above the molding surrounding the first die and the second die.

5. The apparatus of claim 1 further comprising a wire bond configured to provide an electrical path for the power signal to the second die through the heat spreader.

6. The apparatus of claim 1, wherein the heat spreader is part of a power distribution network that provides power to the second die, the power distribution network configured to bypass going through the first die when providing power to the second die.

7. The apparatus of claim 1, wherein the second die comprises a via structure comprising a first via and a second via, the first via comprising a first width, the second via comprising a second width, the first width being greater than the second width.

8. The apparatus of claim 7, wherein the first via is coupled to the heat spreader, the second via being coupled to the first via.

9. The apparatus of claim 1, wherein the heat spreader is a patterned heat spreader.

10. The apparatus of claim 1, wherein the apparatus is incorporated into at least one of a music player, a video player, an entertainment unit, a navigation device, a communications device, a mobile phone, a smartphone, a personal digital assistant, a fixed location terminal, a tablet computer, and/or a laptop computer.

11. An apparatus comprising:
a package substrate;
a first die coupled to the package substrate;
a second die coupled to the first die; and
a heat dissipating means for heat dissipation and power distribution of the second die.

12. The apparatus of claim 11 further comprising a molding surrounding the first die and the second die.

13. The apparatus of claim 12, wherein the heat dissipating means comprises a heat spreader configured to (i) dissipate heat from the second die, and (ii) provide an electrical path for a power signal to the second die.

14. The apparatus of claim 13, wherein the heat dissipating means further comprises a plurality of through mold vias (TMVs) coupled to the heat spreader, the plurality of TMVs configured to provide an electrical path for the power signal to the second die through the heat spreader.

15. The apparatus of claim 11, wherein the heat dissipating means is above the molding surrounding the first die and the second die.

15. The apparatus of claim 11 further comprising a wire bond configured to provide an electrical path for the power signal to the second die through the heat dissipating means.

16. The apparatus of claim 11, wherein the heat dissipating means is part of a power distribution network that provides power to the second die, the power distribution network configured to bypass going through the first die when providing power to the second die.

17. The apparatus of claim 11, wherein the second die comprises a via structure comprising a first via and a second via, the first via comprising a first width, the second via comprising a second width, the first width being greater than the second width.

18. The apparatus of claim 17, wherein the first via is coupled to the heat dissipating means, the second via being coupled to the first via.

19. The apparatus of claim 11, wherein the heat dissipating means comprises a patterned heat spreader.

20. The apparatus of claim 11, wherein the apparatus is incorporated into at least one of a music player, a video player, an entertainment unit, a navigation device, a communications device, a mobile phone, a smartphone, a personal digital assistant, a fixed location terminal, a tablet computer, and/or a laptop computer.

21. A method for providing a package, comprising:
providing a package substrate;
providing a first die coupled to the package substrate;
providing a second die coupled to the first die; and
providing a heat spreader coupled to the second die, the heat spreader configured to (i) dissipate heat from the second die, and (ii) provide an electrical path for a power signal to the second die.

22. The method of claim 21 further comprising:
providing a molding surrounding the first die and the second die; and
providing a plurality of through mold vias (TMVs) coupled to the heat spreader, the plurality of TMVs configured to provide an electrical path for the power signal to the second die through the heat spreader.

23. The method of claim 22, wherein the plurality of TMVs traverse the molding.

24. The method of claim 22, wherein the heat spreader is above the molding surrounding the first die and the second die.

25. The method of claim 21 further comprising providing a wire bond configured to provide an electrical path for the power signal to the second die through the heat spreader.

26. The method of claim 21, wherein the heat spreader is part of a power distribution network that provides power to the second die, the power distribution network configured to bypass going through the first die when providing power to the second die.

27. The method of claim 21, wherein the second die comprises a via structure comprising a first via and a second via, the first via comprising a first width, the second via comprising a second width, the first width being greater than the second width.

28. The method of claim 27, wherein the first via is coupled to the heat spreader, the second via being coupled to the first via.

29. The method of claim 21, wherein the heat spreader is a patterned heat spreader.

30. The method of claim 21, further comprising incorporating the package into at least one of a music player, a video player, an entertainment unit, a navigation device, a communications device, a mobile phone, a smartphone, a personal digital assistant, a fixed location terminal, a tablet computer, and/or a laptop computer.
